(19) United States
(12) Patent Application Publication
(10) Pub. No.: US 2013/0037830 A1
(43) Pub. Date: Feb. 14, 2013

(54) LIGHT EMITTING DIODE PACKAGE AND METHOD FOR MANUFACTURING THE SAME

(71) Applicant: Jong-Jin JANG, Suwon-si (KR)

(72) Inventor: Jong-Jin JANG, Suwon-si (KR)

(73) Assignees: DOOSUNG ADVANCED TECHNOLOGY CO., LTD., Suwon-si (KR); Jong-Jin JANG, Suwon-si (KR)

(21) Appl. No.: 13/560,241

(22) Filed: Jul. 27, 2012

(30) Foreign Application Priority Data
Aug. 10, 2011 (KR) 10-2011-0079702

(51) Int. Cl. H01L 33/48; H01L 33/60

(52) U.S. Cl. 257/88; 438/27; 257/E33.068; 257/E33.056

(57) ABSTRACT

A light emitting diode package includes a heat-dissipating substrate including a reflective groove having a lower bottom surface, an upper opening having a width greater than the lower bottom surface, and an inclined surface formed between the upper opening and the lower bottom surface and mounting grooves, each formed in the reflective groove and having a lower bottom surface, an upper opening having a width greater than the lower bottom surface, and an inclined surface formed between the upper opening and the lower bottom surface; an insulating layer selectively formed on the heat-dissipating substrate; wiring pattern layers formed on the insulating layer and extending to bottom surfaces of the mounting grooves to be selectively formed thereon; a light emitting diode chip mounted in each of the mounting grooves; and a molding layer formed around the light emitting diode chip.

### CROSS-REFERENCE TO RELATED PATENT APPLICATION

This application claims the benefit of Korean Patent Application No. 10-2011-0079702, filed on Aug. 10, 2011, in the Korean Intellectual Property Office, the disclosure of which is incorporated herein in its entirety by reference.

### BACKGROUND OF THE INVENTION

1. Field of the Invention

The present invention relates to a light emitting diode unit and, more particularly, to a light emitting diode package and a method for manufacturing the same, which can facilitate a chip bonding process and reduce the thickness of the package by using a heat-dissipating substrate having a multilayer reflective surface and by extending a wiring pattern layer to a lower bottom surface of a chip mounting area.

2. Description of the Related Art

A light emitting diode is an electronic device that produces minority carriers (electrons or holes) injected using p-n junctions in semiconductors and emits light by recombination of the minority carriers.

The light emitting diode has been used in various fields and has recently attracted much attention as a replacement for fluorescent lamps since its lifespan is semi-permanent and it has no toxic substances regulated by environmental regulations (such as RoHS, ELV, PFOS, etc.).

Typically, a light emitting diode chip is packaged in such a manner that the light emitting diode chip is bonded on a lead frame with Ag, for example, an N-type pad and a P-type pad of the light emitting diode chip are wire-bonded thereto, and then the resulting chip is sealed by epoxy molding.

The light emitting diode package configured in the above manner is mounted on a heat-dissipating plate for heat dissipation and then installed on a printed circuit board (PCB), or otherwise mounted on a PCB by surface mount technology (SMT), for example, and then attached on a heat-dissipating plate.

Moreover, a light emitting diode array unit used in an LCD backlight, etc. for example, is manufactured by arranging a plurality of light emitting diode packages configured in the above manner on a PCB in the form of an array by surface mount technology (SMT), for example.

The light emitting diode array unit configured in the above manner is attached on a heat-dissipating plate for heat dissipation.

As such, conventionally, in order to manufacture the light emitting diode unit, it is necessary to employ a plurality of manufacturing processes having different characteristics such as a process of manufacturing the lead frame, a process of manufacturing the heat-dissipating plate, a process of manufacturing the light emitting diode package, a process of manufacturing the PCB, a process of mounting the light emitting diode package, etc.

That is, the light emitting diode cannot be exclusively manufactured by a single manufacturer but can be manufactured through the cooperation of other manufacturers. Thus, the manufacturing process of the light emitting diode unit is complicated and the manufacturing costs of the light emitting diode unit are increased, which is problematic.

Moreover, conventionally, the light emitting diode chip is mounted on the lead frame and packaged, and the light emitting diode package is mounted on the PCB. Thus, the overall thickness of the light emitting diode unit is increased, which is an obstacle to thinning of an electronic product employing the light emitting diode unit.

In particular, conventionally, for the heat dissipation of the light emitting diode, the light emitting diode chip is mounted on the lead frame and packaged, and then the light emitting diode package is installed on the PCB with the heat-dissipating plate interposed therebetween, or otherwise the light emitting diode package is mounted on the PCB and then connected to the heat-dissipating plate.

As a result, the overall thickness of the light emitting diode unit is increased, which is an obstacle to thinning of an electronic product employing the light emitting diode unit.

The light emitting diode unit of the prior art has limitations in improving the wavelength conversion efficiency of emitted light, and thus it is difficult to increase the light output, brightness, or color rendering.

### SUMMARY OF THE INVENTION

The present invention has been made in an effort to solve the above-described problems associated with prior art, and an object of the present invention is to provide a light emitting diode package and a method for manufacturing the same, which can facilitate a chip bonding process and reduce the thickness of the package by using a heat-dissipating substrate having a multilayer reflective surface and by extending a wiring pattern layer to a lower bottom surface of a chip mounting area.

Another object of the present invention is to provide a light emitting diode package and a method for manufacturing the same, which can increase the reflection efficiency of emitted light by forming a reflective groove having a reflective surface in a chip mounting area of a heat-dissipating substrate and forming a plurality of mounting grooves having other reflective surfaces in the reflective groove.

Still another object of the present invention is to provide a light emitting diode package and a method for manufacturing the same, which can significantly simplify a process of manufacturing the light emitting diode package and significantly reduce its manufacturing costs.

Yet another object of the present invention is to provide a light emitting diode package and a method for manufacturing the same, which can simplify a process of manufacturing the light emitting diode package and its structure by mounting a light emitting diode chip directly on a heat-dissipating substrate.

The objects of the present invention are not limited to the above-mentioned objects, and other objects that are not mentioned will be clearly understood by those skilled in the art from the following description.

According to an aspect of the present invention to achieve the above object of the present invention, there is provided a light emitting diode package comprising: a heat-dissipating substrate including a reflective groove having a lower bottom surface, an upper opening having a width greater than that of the lower bottom surface, and an inclined surface formed between the upper opening and the lower bottom surface and a plurality of mounting grooves, each formed in the reflective groove and having a lower bottom surface, an upper opening having a width greater than that of the lower bottom surface, and an inclined surface formed between the upper opening and the lower bottom surface; an insulating layer selectively formed on the heat-dissipating substrate; wiring pattern layers formed on the insulating layer and extending to bottom surfaces of the mounting grooves to be selectively formed thereon; a light emitting diode chip mounted in each of the mounting grooves; and a molding layer formed around the light emitting diode chip.

The inclined surface of the mounting grooves may be used as a first reflective surface and the inclined surface of the reflective groove may be used as a second reflective surface.

The light emitting diode package may further comprise a bonding wire electrically connecting electrode pads of the light emitting diode chip to the wiring pattern layers.

The wiring pattern layers may have a structure in which first, second, and third wiring pattern-forming material layers are sequentially stacked using materials such as Cu, Ni and Ag.

According to another aspect of the present invention to achieve the above object of the present invention, there is provided a method for manufacturing a light emitting diode package, the method comprising: forming a reflective groove having an inclined surface on a heat-dissipating substrate and forming mounting grooves having another inclined surface in the reflective groove; forming an insulating layer selectively on the heat-dissipating substrate and forming wiring pattern layers extending to bottom surfaces of the mounting grooves on the insulating layer; mounting a light emitting diode chip in each of the mounting grooves of the heat-dissipating substrate; and electrically connecting electrode pads of the light emitting diode chip to the wiring pattern layers by wire bonding and forming a molding layer around a chip mounting area in which each of the light emitting diode chips is mounted.

The reflective groove may be formed to have a lower bottom surface, an upper opening having a width greater than that of the lower bottom surface, and an inclined surface formed between the upper opening and the lower bottom surface, and each of the mounting grooves may be formed to have a lower bottom surface, an upper opening having a width greater than that of the lower bottom surface, and an inclined surface formed between the upper opening and the lower bottom surface.

The reflective groove and the mounting grooves may be formed by press bending, die-casting, numerical control (NC) or etching.

The heat-dissipating substrate may comprise aluminum or magnesium and the insulating layer may comprise ceramic or aluminum oxide.

The wiring pattern layers may have a structure in which first, second, and third wiring pattern-forming material layers are sequentially stacked using materials such as Cu, Ni and Ag, the first wiring pattern-forming material layer may be selectively formed by sputtering, and the second and third wiring pattern-forming material layers may be sequentially formed on the first wiring pattern-forming material layer by plating.

The molding layer may be formed into a lens shape by coating a mixture prepared by mixing phosphor, a fluorescent material, with silicone in a predetermined mixing ratio.

### BRIEF DESCRIPTION OF THE DRAWINGS

The above and other features and advantages of the present invention will become more apparent by describing in detail exemplary embodiments thereof with reference to the attached drawings in which:

FIGS. 1A to 1F are cross-sectional views showing a process of manufacturing a light emitting diode package according to the present invention;

FIG. 2 is an enlarged view showing a chip bonding area of a light emitting diode package according to the present invention; and

FIG. 3 is a view illustrating an insulating layer that may be selectively removed to pattern a chip mounting area in which a light emitting diode is mounted to be opened in a subsequent process.

### DETAILED DESCRIPTION OF THE INVENTION

Hereinafter, preferred embodiments of a light emitting diode package and a method for manufacturing the same according to the present invention will be described in detail with reference to the accompanying drawings.

Features and advantages of the light emitting diode package and the method for manufacturing the same according to the present invention will be apparent from the following detailed description of the preferred embodiment of the present invention.

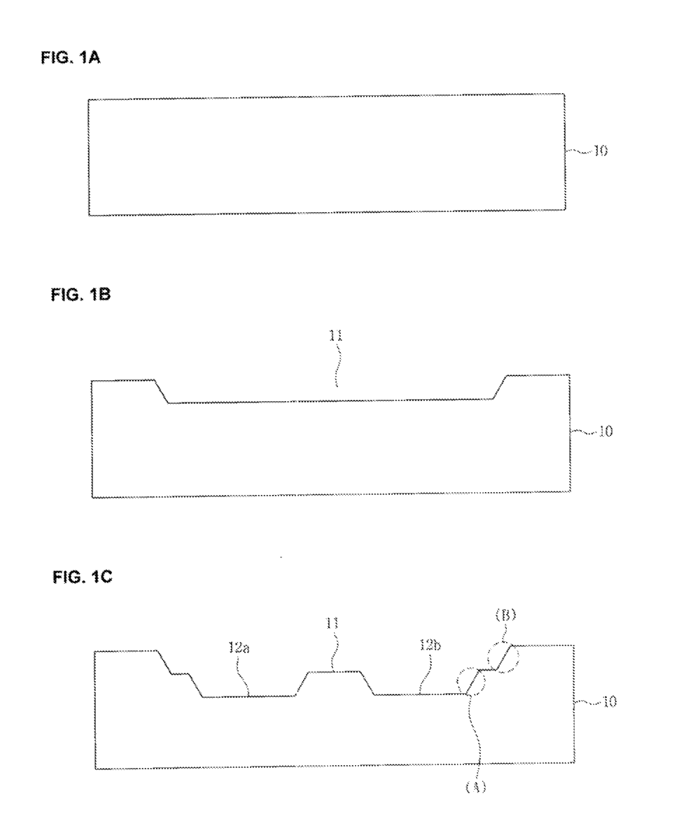

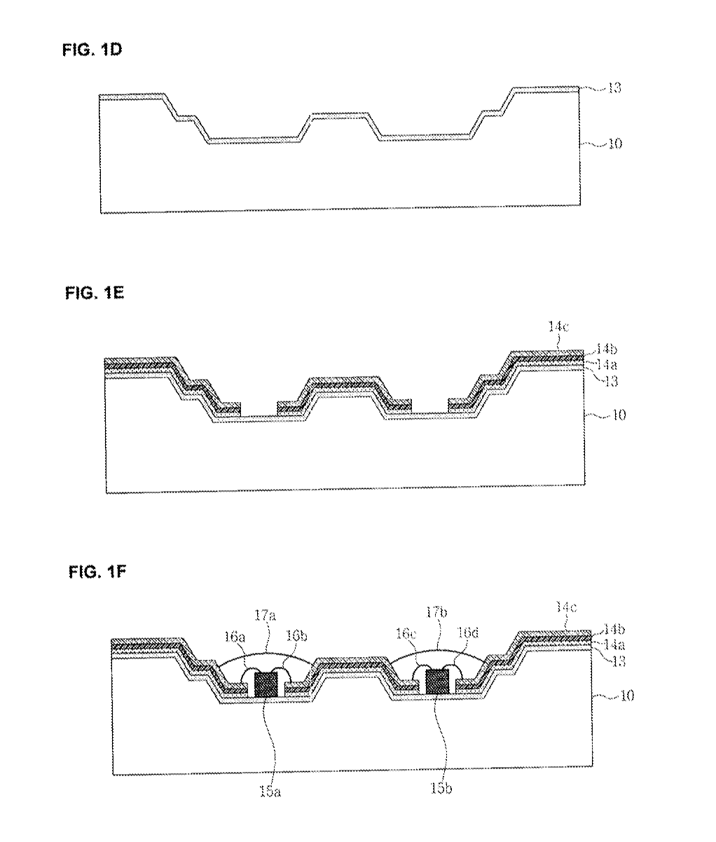

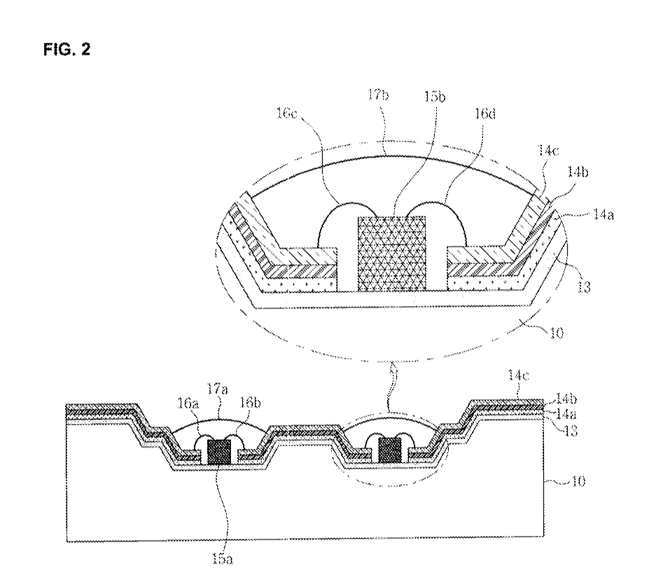

FIGS. 1A to 1F are cross-sectional views showing a process of manufacturing a light emitting diode package according to the present invention, and FIG. 2 is an enlarged view showing a chip bonding area of a light emitting diode package according to the present invention.

The present invention aims at providing a light emitting diode package and a method for manufacturing the same, which can facilitate a chip bonding process and reduce the thickness of the package by using a heat-dissipating substrate having a multilayer reflective surface and by extending a wiring pattern layer to a lower bottom surface of a chip mounting area.

The heat-dissipating substrate used in the light emitting diode package according to the present invention can increase the reflection efficiency of emitted light by forming a reflective groove having a reflective surface in a chip mounting area and forming a plurality of mounting grooves having other reflective surfaces in the reflective groove.

A heat-dissipating substrate 10 having a multilayer reflective surface according to the present invention comprises a reflective groove 11 having a lower bottom surface formed in the chip mounting area of the heat-dissipating substrate 10, an upper opening having a width greater than that of the lower bottom surface, and an inclined surface formed between the upper opening and the lower bottom surface and a plurality of mounting grooves 12a and 12b, each formed in the reflective groove 11 and having a lower bottom surface, an upper opening having a width greater than that of the lower bottom surface, and an inclined surface formed between the upper opening and the lower bottom surface, the inclined surface of the reflective groove 11 being used as a second reflective layer B and the inclined surface of the mounting grooves 12a and 12b being used as a first reflective layer A.

Here, a light emitting diode chip is mounted on the bottom surface of each of the mounting grooves 12a and 12b, and light emitted from each of the light emitting diode chip is reflected from a multilayer reflective structure comprising the second reflective layer and the first reflective layer.

The above-described heat-dissipating substrate having the multilayer reflective surface according to the present invention can improve the reflection efficiency by the multilayer reflective structure comprising the second reflective layer and the first reflective layer and further enable thinning of the device by the multilayer reflection under the surface of the heat-dissipating substrate.

The light emitting diode package according to the present invention comprises the heat-dissipating substrate 10 made of a material having excellent thermal conductivity, the reflective groove 11 having the lower bottom surface formed in the chip mounting area of the heat-dissipating substrate 10, the upper opening having a width greater than that of the lower bottom, and the inclined surface formed between the upper opening and the lower bottom surface, the plurality of mounting grooves 12a and 12b, each formed in the reflective groove 11 and having the lower bottom surface, the upper opening having a width greater than that of the lower bottom surface, and the inclined surface formed between the upper opening and the lower bottom surface, an insulating layer 13 made of ceramic or aluminum oxide and selectively formed in the chip mounting area of the heat-dissipating substrate 10, wiring pattern layers 14a, 14b and 14c formed on the insulating layer 13 to correspond to the light emitting diode chips mounted in the mounting grooves 12a and 12b in the reflective groove 11 and extending to the bottom surfaces of the mounting grooves 12a and 12b to be selectively formed thereon, one or more light emitting diode chips 15a and 15b mounted in the mounting grooves 12a and 12b of the heat-dissipating substrate 10 and each including an N-type pad and a P-type pad, bonding wires 16a, 16b, 16c and 16d electrically connecting the pads of the light emitting diode chips 15a and 15b to the wiring pattern layers 14a, 14b and 14c, and molding layers 17a and 17b formed around the light emitting diode chips 15a and 15b mounted in the chip mounting areas.

Here, the molding layers 17a and 17b fill the concave chip mounting areas formed by the mounting grooves 12a and 12b having the inclined surface, and their top surfaces may be in the form of a convex lens. The molding layers 17a and 17b may be formed by coating a YAG fluorescent material (such as yellow phosphor), silicone, or a mixture thereof such that the light emitting diode chips emit white light.

The upper height of each of the molding layers 17a and 17b may depend on the radiation angle, radiation intensity, etc. of emitted light.

The above-described light emitting diode package according to the present invention has a structure in which the inclined surface of the mounting grooves 12a and 12b are used as the first reflective surface and the inclined surface of the reflective groove 11 are used as the second reflective surface.

A process of manufacturing the above-described light emitting diode package according to the present invention will now be described.

First, as shown in FIG. 1A, a heat-dissipating substrate 10 made of a metal material with excellent heat dissipation performance and excellent light reflectance such as aluminum, magnesium, etc. is prepared, and as shown in FIG. 1B, a reflective groove 11 recessed with inclined surface, whose opening width increases as it goes outward from the flat bottom surface, is formed in a chip mounting area of the heat-dissipating substrate 10.

Here, the reflective groove 11 of the heat-dissipating substrate 10 may be formed by press bending, die-casting, numerical control (NC) or etching.

Subsequently, as shown in FIG. 1C, a plurality of mounting grooves 12a and 12b, each having a lower bottom surface, an upper opening having a width greater than that of the lower bottom surface, and inclined surface formed between the upper opening and the lower bottom surface, are formed in the reflective groove 11 of the heat-dissipating substrate 10.

Likewise, the mounting grooves 12a and 12b of the heat-dissipating substrate 10 may be formed by press bending, die-casting, numerical control (NC) or etching.

Then, as shown in FIG. 1D, an insulating layer 13 made of an insulating material such as ceramic or aluminum oxide is formed on the heat-dissipating substrate 10 on which the reflective groove 11 and the mounting grooves 12a and 12b are formed.

Here, the insulating layer 13 may be formed by plating or coating ceramic or aluminum oxide or by aluminum oxidation (heat-dissipating substrate) and may have a thickness of 3 to 50 μm for light reflection and insulation withstand voltage.

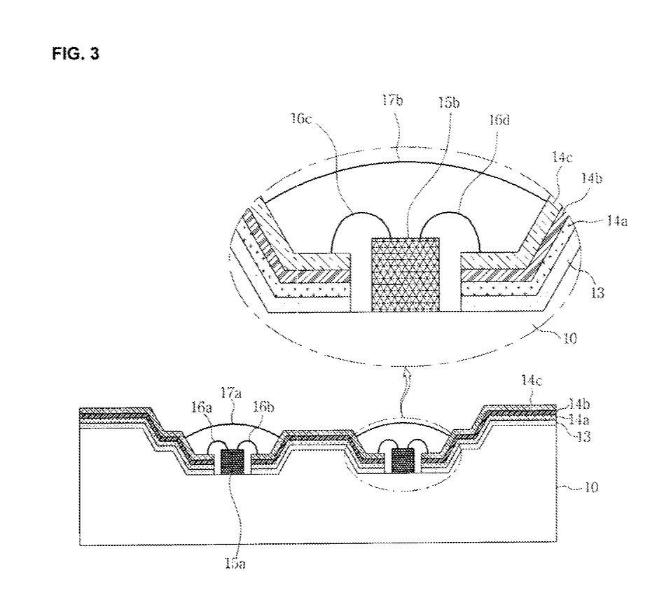

Here, as shown in FIG. 3, the insulating layer 13 may be selectively removed to pattern the chip mounting area in which the light emitting diode is mounted to be opened in a subsequent process.

Moreover, as shown in FIG. 1E, first, second, and third wiring pattern-forming material layers are formed on the patterned insulating layer 13 using materials having excellent electrical conductivity such as Cu, Ni and Ag, thus forming wiring pattern layers 14a, 14b and 14c.

Here, the Ni is used as the second wiring pattern-forming material layer to allow the Ag used as the third wiring pattern-forming material layer to be plated directly on a Cu layer used as the first wiring pattern-forming material layer.

The Ag used as the third wiring pattern-forming material layer is to improve the reflectance and facilitate a wire bonding process.

The Cu layer used as the first wiring pattern-forming material layer may be selectively formed in a desired area by forming a mask layer and sputtering the mask layer.

The wiring pattern layers 14a, 14b and 14c are selectively formed to extend to the bottom surfaces of the mounting grooves 12a and 12b.

Subsequently, as shown in FIG. 1F, a bonding layer (not shown) is formed on the center of the chip mounting area of the heat-dissipating substrate 10, and light emitting diode chips 15a and 15b are bonded thereto.

An example of the light emitting diode chips 15a and 15b has a structure in which an N-area and a P-area are stacked on a sapphire substrate with an active area interposed therebetween, an N-type pad is formed on the N-area, and a P-type pad is formed on the P-area.

Then, electrode pads of the light emitting diode chips 15a and 15b are wire-bonded to the wiring pattern layers 14a, 14b and 14c using bonding wires 16a, 16b, 16c and 16d.

Lastly, molding layers 17a and 17b are formed around the chip mounting areas of the heat-dissipating substrate 10.

According to the above-described light emitting diode package of the present invention, it is possible to increase the reflection efficiency of light by forming the plurality of mounting grooves having the reflective surfaces on the heat-dissipating substrate and mounting the light emitting diode chip in each mounting groove such that the light emitting diode chip has multiple reflective surfaces and to further increase the reflection efficiency by the multilayer reflection under the surface of the heat-dissipating substrate.

Moreover, according to the light emitting diode package of the present invention, it is possible to facilitate the chip bonding process and reduce the thickness of the package by using the heat-dissipating substrate having the multilayer reflective surface and by extending the wiring pattern layers to the lower bottom surface of the chip mounting areas.

As described above, the light emitting diode package and the method for manufacturing the same according to the present invention have the following effects.

First, it is possible to facilitate the chip bonding process and reduce the thickness of the package by using the heat-dissipating substrate having the multilayer reflective surface and by extending the wiring pattern layers to the lower bottom surface of the chip mounting area.

Second, it is possible to increase the reflection efficiency of emitted light by forming the reflective groove having the reflective surface in the chip mounting area of the heat-dissipating substrate and forming the plurality of mounting grooves having other reflective surfaces in the reflective groove.

Third, it is possible to significantly simplify the process of manufacturing the light emitting diode package and significantly reduce its manufacturing costs.

Fourth, it is possible to simplify the process of manufacturing the light emitting diode package and its structure and significantly reduce the overall thickness by mounting the light emitting diode chip directly on the heat-dissipating substrate, thus suitably applying the light emitting diode package to an electronic device that requires thinning.

Fifth, it is possible to increase the reflection efficiency by the multilayer reflection under the surface of the heat-dissipatng substrate, which is advantageous to thinning.

While the invention has been shown and described with reference to certain preferred embodiments thereof, it will be understood by those skilled in the art that various changes in form and details may be made therein without departing from the spirit and scope of the invention as defined by the appended claims.

Therefore, the scope of the invention is defined not by the detailed description of the invention but by the appended claims, and all differences within the scope will be construed as being included in the present invention.

What is claimed is:

1. A light emitting diode package comprising:
a heat-dissipating substrate including a reflective groove having a lower bottom surface, an upper opening having a width greater than that of the lower bottom surface, and an inclined surface formed between the upper opening and the lower bottom surface and a plurality of mounting grooves, each formed in the reflective groove and having a lower bottom surface, an upper opening having a width greater than that of the lower bottom surface, and an inclined surface formed between the upper opening and the lower bottom surface;
an insulating layer selectively formed on the heat-dissipating substrate;
wiring pattern layers formed on the insulating layer and extending to bottom surfaces of the mounting grooves to be selectively formed thereon;
a light emitting diode chip mounted in each of the mounting grooves; and
a molding layer formed around the light emitting diode chip.

2. The light emitting diode package of claim 1, wherein the inclined surface of the mounting grooves is used as a first reflective surface and the inclined surface of the reflective groove is used as a second reflective surface.

3. The light emitting diode package of claim 1, further comprising a bonding wire electrically connecting electrode pads of the light emitting diode chip to the wiring pattern layers.

4. The light emitting diode package of claim 1, wherein the wiring pattern layers have a structure in which first, second, and third wiring pattern-forming material layers are sequentially stacked using materials such as Cu, Ni and Ag.

5. A method for manufacturing a light emitting diode package, the method comprising:
forming a reflective groove having an inclined surface on a heat-dissipating substrate and forming mounting grooves having another an inclined surface in the reflective groove;
forming an insulating layer selectively on the heat-dissipating substrate and forming wiring pattern layers extending to bottom surfaces of the mounting grooves on the insulating layer;
mounting a light emitting diode chip in each of the mounting grooves of the heat-dissipating substrate; and
electrically connecting electrode pads of the light emitting diode chip to the wiring pattern layers by wire bonding and forming a molding layer around a chip mounting area in which each of the light emitting diode chips is mounted.

6. The method of claim 5, wherein the reflective groove is formed to have a lower bottom surface, an upper opening having a width greater than that of the lower bottom surface, and an inclined surface formed between the upper opening and the lower bottom surface, and
wherein each of the mounting grooves is formed to have a lower bottom surface, an upper opening having a width greater than that of the lower bottom surface, and an inclined surface formed between the upper opening and the lower bottom surface.

7. The method of claim 5, wherein the reflective groove and the mounting grooves are formed by press bending, die-casting, numerical control (NC) or etching.

8. The method of claim 5, wherein the heat-dissipating substrate comprises aluminum or magnesium and the insulating layer comprises ceramic or aluminum oxide.

9. The method of claim 5, wherein the wiring pattern layers have a structure in which first, second, and third wiring pattern-forming material layers are sequentially stacked using materials such as Cu, Ni and Ag, and
wherein the first wiring pattern-forming material layer is selectively formed by sputtering and the second and third wiring pattern-forming material layers are sequentially formed on the first wiring pattern-forming material layer by plating.

10. The method of claim 5, wherein the molding layer is formed into a lens shape by coating a mixture prepared by mixing phosphor, a fluorescent material, with silicone in a predetermined mixing ratio.
